(19) United States
(12) Patent Application Publication
(10) Pub. No.: US 2018/0228027 A1
(43) Pub. Date: Aug. 9, 2018

(54) ELECTRO-OPTICAL DEVICE AND ELECTRONIC APPARATUS

(71) Applicant: SEIKO EPSON CORPORATION, Tokyo (JP)

(72) Inventor: Suguru UCHIYAMA, Suwa-shi (JP)

(73) Assignee: SEIKO EPSON CORPORATION, Tokyo (JP)

(21) Appl. No.: 15/886,276

(22) Filed: Feb. 1, 2018

(30) Foreign Application Priority Data
Feb. 6, 2017 (JP) 2017-019309

(51) Int. Cl. H05K 1/14; H01L 23/50; H05K 1/02

(52) U.S. Cl. CPC H05K 1/144; H05K 1/0203; H05K 1/028; H01L 23/50

(57) ABSTRACT

A first mounting substrate and a second mounting substrate connected to the electro-optical panel have all the same configurations including mounting positions of a first drive IC and a second drive IC for the first flexible wiring substrate and the second flexible wiring substrate. A total sum of thicknesses of the first flexible wiring substrate, the second flexible wiring substrate, the first drive IC, and the second drive IC is equal to or less than a thickness of an electro-optical panel. A first heat dissipating plate portion and a second heat dissipation plate portion are provided on both sides of a part where the first drive IC and the second drive IC are mounted, in a thickness direction.

### BACKGROUND

### 1. Technical Field

The present invention relates to an electro-optical device including an electro-optical panel to which a wiring substrate is connected, and an electronic apparatus.

### 2. Related Art

An electro-optical device such as a liquid crystal display device or an organic electroluminescence device often adopts a structure in which a flexible wiring substrate is connected to an element substrate having a pixel region in which a plurality of pixel electrodes are arranged, and a drive IC is connected to the flexible wiring substrate. Meanwhile, in order to cope with high resolution, miniaturization of an electro-optical device, and the like, a structure in which two flexible wiring substrates having drive ICs mounted thereon are connected to one end of an element substrate has been proposed (refer to JP-A-2016-14755).

If a plurality of flexible wiring substrates on which drive ICs are mounted are used as in the configuration described in JP-A-2016-14755, a display area (pixel area) of the electro-optical device increases in size. In addition, the electro-optical device increases in thickness due to a thickness of each of the drive ICs mounted on the plurality of flexible wiring substrates or a heat dissipation structure thereof. In addition, in a case where the electro-optical device is mounted on an electronic apparatus such as a projection type display device, a connection with a high-level circuit or the like is complicated. Furthermore, the flexible wiring substrate on which the drive IC is mounted is expensive.

### SUMMARY

An advantage of some aspects of the invention is to provide an electro-optical device that can be miniaturized and can reduce an increase in cost even if a plurality of wiring substrates on which drive ICs are mounted are used, and an electronic apparatus.

According to an aspect of the invention, there is provided an electro-optical device including an electro-optical panel, a first mounting substrate that is connected to one side of the electro-optical panel, and a second mounting substrate that is connected to the one side of the electro-optical panel, in which at least parts of the first mounting substrate and the second mounting substrate overlap each other in plan view, in which the first mounting substrate includes a first flexible wiring substrate and a first drive IC that is mounted on one surface of the first flexible wiring substrate, in which the second mounting substrate includes a second flexible wiring substrate and a second drive IC that is mounted on one surface of the second flexible wiring substrate, in which at least parts of the first drive IC and the second drive IC overlap each other in plan view, and in which a total sum of thicknesses of the first mounting substrate and the second mounting substrate is larger than a thickness of the electro-optical panel at a place where the first drive IC and the second drive IC overlap each other.

In the aspect of the invention, a first mounting substrate and a second mounting substrate are connected to an electro-optical panel in a state of overlapping. Accordingly, it is possible to reduce a size of the electro-optical panel (electro-optical device).

In addition, since a total sum of thicknesses of a first mounting substrate and a second mounting substrate is equal to or less than a thickness of an electro-optical panel, there is an advantage that a thickness of the part where a heat dissipation portion is provided is reduced, even in a case where a heat dissipation plate portion that overlaps a part where drive ICs of a plurality of mounting substrates are mounted, from both sides of the electro-optical panel in a thickness direction is provided in a holder that supports an electro-optical panel from both sides in the thickness direction. Therefore, even when a plurality of mounting substrates on which drive ICs are mounted are used, it is possible to realize an electro-optical device that can be miniaturized and can reduce an increase in cost.

In the aspect of the invention, it may be possible to adopt an aspect in which the first mounting substrate and the second mounting substrate are the same in size. According to the aspect, there is no need to prepare a plurality of types of mounting substrates. Thus, cost can be reduced.

In the aspect of the invention, it is possible to adopt an aspect in which parts of the respective drive ICs overlap with each other in a thickness direction in the plurality of mounting substrates. According to the aspect, since the drive ICs which are heat generating sources are collected, it is easy to take measure against heat by using a heat dissipation plate portion.

In the aspect of the invention, it is possible to adopt an aspect in which, in each of the plurality of mounting substrates, an electronic component in addition to the drive IC is mounted on the flexible wiring substrate, and in the plurality of mounting substrates, the respective electronic components do not overlap in a thickness direction.

In the aspect of the invention, it is possible to adopt an aspect in which each of the plurality of mounting substrates has one surface connected to the electro-optical panel. According to the aspect, in a mounting substrate, an electrode for being mounted on an electro-optical panel and an electrode for mounting a drive IC can be provided on the same surface (one surface) of a flexible wiring substrate. Thus, in a mounting substrate, a flexible wiring substrate can be a single-sided substrate, and thus, cost can be reduced.

In the aspect of the invention, it is possible to adopt an aspect in which, in each of the plurality of mounting substrates, an extension substrate configured by a flexible wiring substrate is connected to an end portion on a side opposite to a side of the electro-optical panel with respect to the drive IC of the flexible wiring substrate. According to the aspect, an expensive flexible wiring substrate used for a mounting substrate can be shortened, and thus, cost can be reduced.

In the aspect of the invention, it may be possible to adopt an aspect in which the electro-optical device further includes a holder that supports the electro-optical panel from both sides in a thickness direction, and the holder includes a first holder member that supports the electro-optical panel from one side in a thickness direction, a second holder member that supports the electro-optical panel from the other side in the thickness direction, a first heat dissipation plate portion that overlaps a part where the drive IC of each of a plurality of the mounting substrates is mounted from one side of the electro-optical panel in a thickness direction, and a second heat dissipation plate portion that overlaps the part where the drive IC of each of the plurality of mounting substrates is mounted from the other side of the electro-optical panel in the thickness direction.

In the aspect of the invention, it may be possible to adopt an aspect in which the electro-optical panel includes an element substrate on which pixel electrodes are formed, a counter substrate facing the element substrate, and a dust-proof glass that is disposed so as to overlap on at least one of a surface of the counter substrate on a side opposite to the element substrate and a surface of the element substrate on a side opposite to the counter substrate.

In the aspect of the invention, it is possible to adopt an aspect in which the two mounting substrates as the plurality of mounting substrates are connected to the electro-optical panel.

An electro-optical device according to the invention can be used for various electronic apparatuses. In a case where the electronic apparatus is a projection type display device, the projection type display device includes a light source unit that emits light supplied to the electro-optical device, and a projection optical system that projects light modulated by the electro-optical device.

### BRIEF DESCRIPTION OF THE DRAWINGS

The invention will be described with reference to the accompanying drawings, wherein like numbers reference like elements.

FIG. 1 is an explanatory view schematically illustrating a state where an aspect of an electro-optical device to which the invention is applied is viewed in an oblique direction.

FIG. 2 is an exploded perspective view in a state where a holder is removed from an electro-optical panel, in the electro-optical device illustrated in FIG. 1.

FIG. 3 is an explanatory view schematically illustrating a planar configuration of the electro-optical panel and the like illustrated in FIG. 1.

FIG. 4 is an explanatory view schematically illustrating a state where the electro-optical panel and the like illustrated in FIG. 1 are cut along the electro-optical panel and a second flexible wiring substrate.

FIG. 5 is a cross-sectional view schematically illustrating a state where the electro-optical device illustrated in FIG. 1 is cut along line V-V.

FIG. 6 is a cross-sectional view schematically illustrating a state where the electro-optical device illustrated in FIG. 1 is cut along line VI-VI.

FIG. 7 is an explanatory diagram illustrating an aspect of an electrical configuration of the electro-optical device illustrated in FIG. 1.

FIG. 8 is a schematic configuration view of a projection type display device which uses the electro-optical device to which the invention is applied.

### DESCRIPTION OF EXEMPLARY EMBODIMENTS

Embodiments of the invention will be described with reference to the drawings. In the drawings referred to in the following description, since the respective members and the like are scaled to a recognizable extent on the drawings, the respective members are scaled differently, and the number of members is reduced. Hereinafter, each direction is represented by using an orthogonal coordinate system configured by the x axis, the y axis, and the z axis.

### Configuration of Electro-Optical Device 1

### Basic Configuration

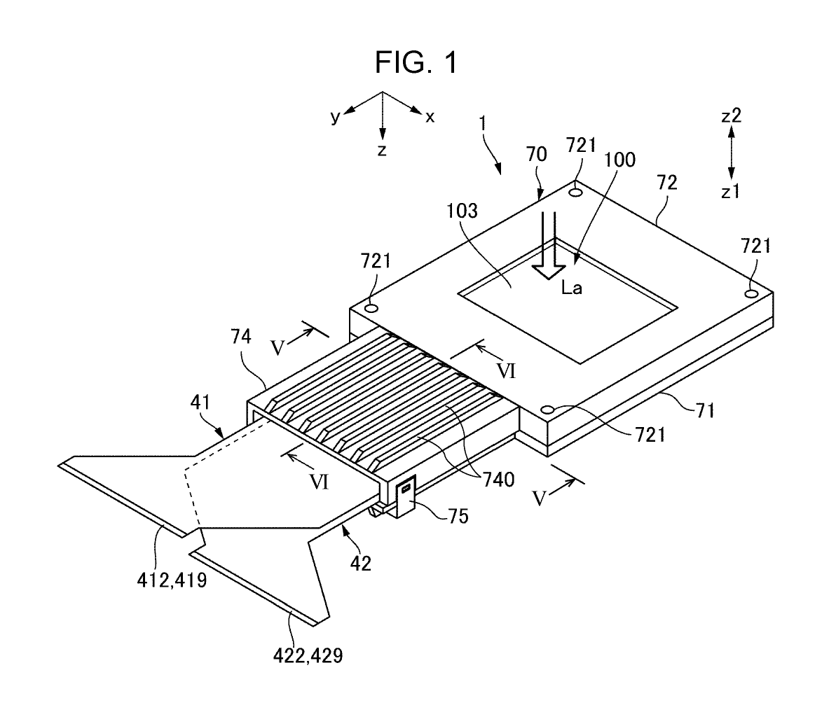

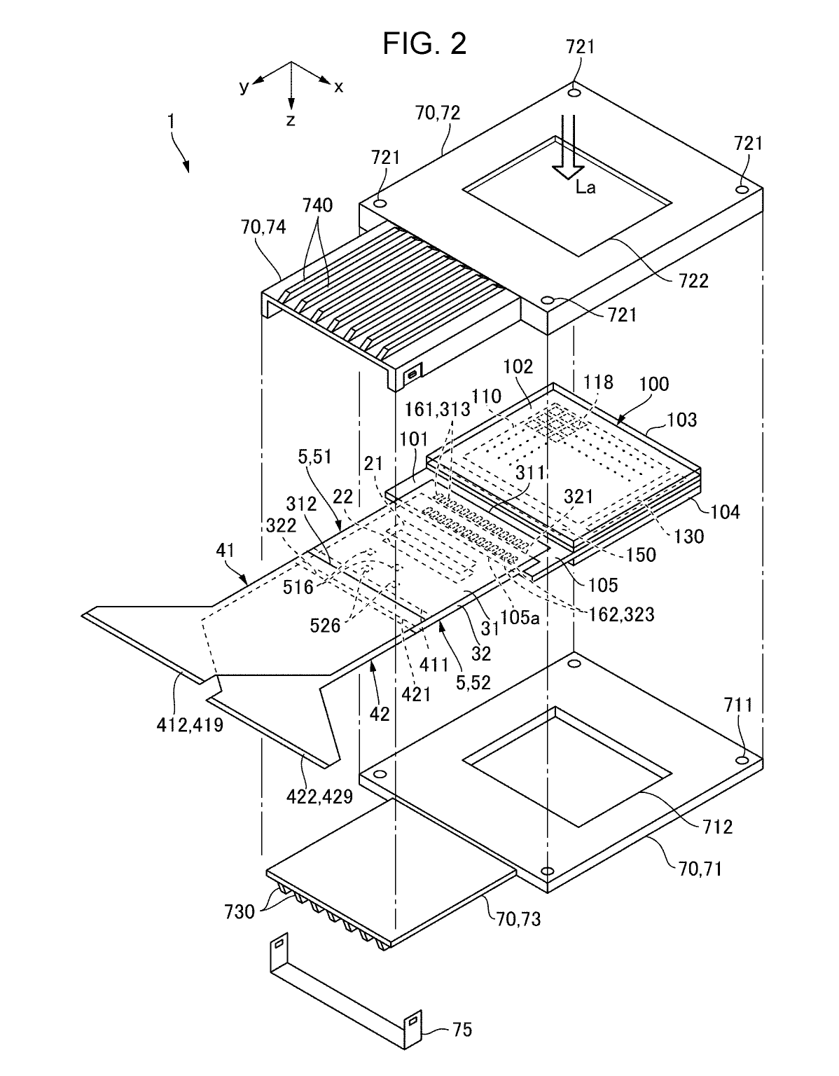

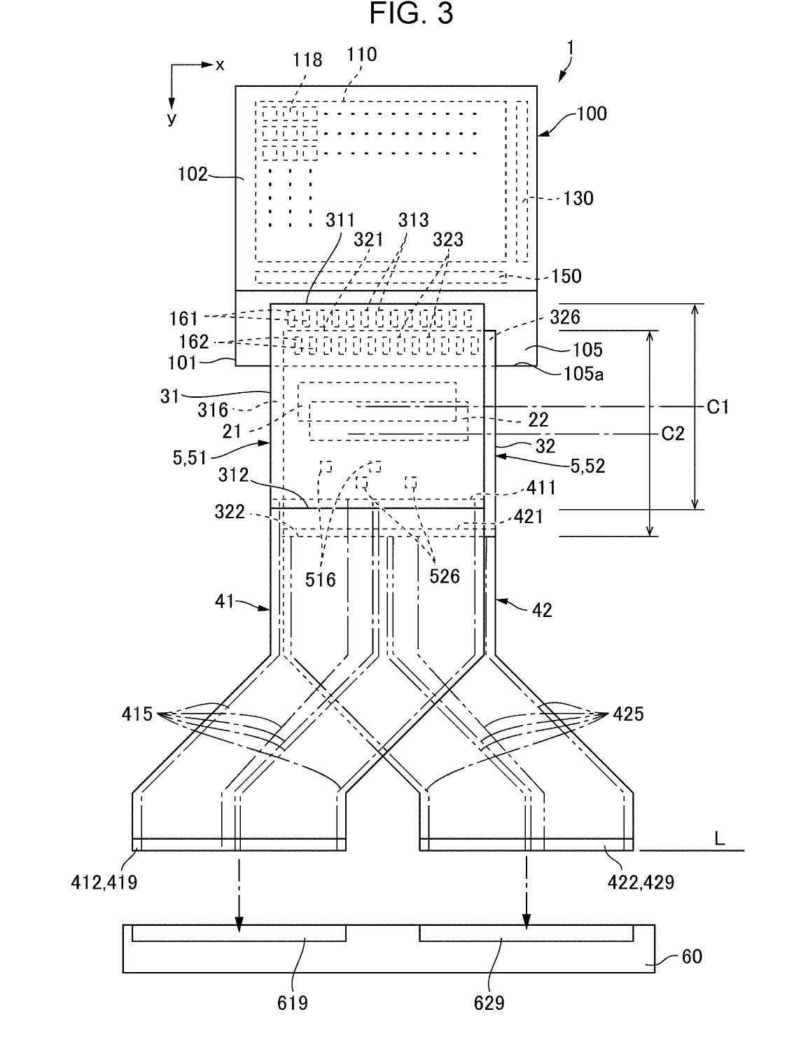

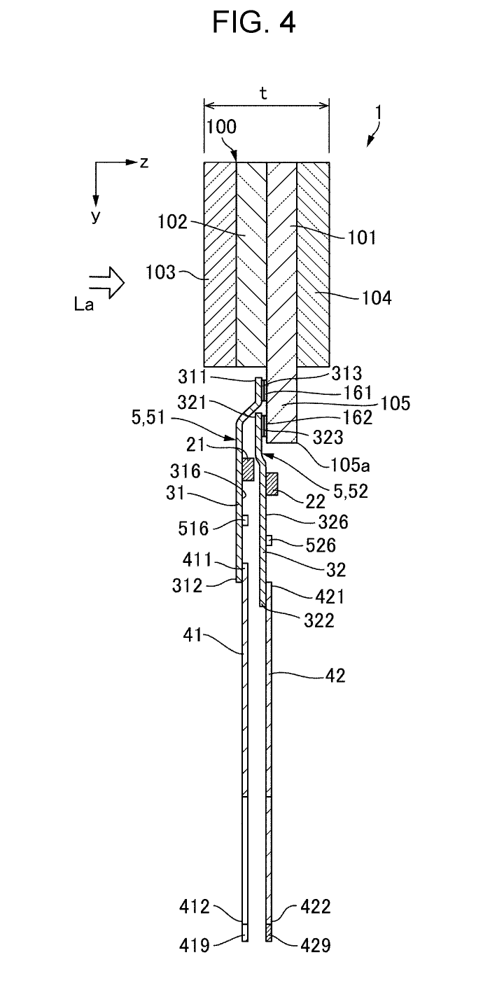

FIG. 1 is an explanatory view schematically illustrating a state where one aspect of an electro-optical device 1 to which the invention is applied is viewed in an oblique direction. FIG. 2 is an exploded perspective view in a state where a holder 70 is removed from an electro-optical panel 100, in the electro-optical device 1 illustrated in FIG. 1. FIG. 3 is an explanatory view schematically illustrating a planar configuration of the electro-optical panel 100 and the like illustrated in FIG. 1. FIG. 4 is an explanatory view schematically illustrating a state where the electro-optical panel 100 and the like illustrated in FIG. 1 are cut along the electro-optical panel 100 and a second flexible wiring substrate 32 in the y direction. FIGS. 2 and 3 illustrate a small number of terminals and wires. In addition, FIGS. 2, 3, and 4, terminals for connecting drive ICs to flexible wiring substrates, terminals for connecting flexible wiring substrates to extension substrates, and the like are omitted.

In FIGS. 1 to 4, the electro-optical device 1 includes an electro-optical panel 100, a plurality of mounting substrates 5 connected to one side of the electro-optical panel 100, and a holder 70 for supporting the electro-optical panel 100 from both sides in a thickness direction (z direction). The electro-optical device 1 is a liquid crystal device used as a light valve or the like which will be described below, and the electro-optical device 1 includes a liquid crystal panel as the electro-optical panel 100.

In the electro-optical panel 100, a counter substrate 102 on which a common electrode (not illustrated) and the like are formed is bonded to an element substrate 101 on which pixel electrodes 118 and the like are formed, by a sealing material (not illustrated). A liquid crystal layer (not illustrated) is provided in a region surrounded by a sealing material, in the electro-optical panel 100. The electro-optical panel 100 according to the present form is a transmissive liquid crystal panel. Accordingly, a light-transmitting substrate such as a heat-resistant glass or a quartz substrate is used for the element substrate 101 and the counter substrate 102.

In the electro-optical panel 100, a region where pixel electrodes 118 are arranged in the x direction and the y direction is a pixel region 110, and in the electro-optical panel 100, a region overlapping the pixel region 110 is a display region. In the element substrate 101, an extension portion 105 that protrudes in the y direction from the counter substrate 102 is provided, and a plurality of terminals including first terminals 161 for receiving an image signal are arranged at a predetermined pitch, along (x direction) an edge (one side 105a) of the extension portion 105. In addition, in the extension portion 105, a plurality of terminals including second terminals 162 for receiving an image signal are arranged at a predetermined pitch in the x direction at a position on a side opposite to the pixel region 110, in which the first terminals 161 are interposed therebetween. Accordingly, the first terminals 161 and the second terminals 162 are arranged along an edge of the element substrate 101 at a position shifted in the y direction. In FIGS. 2 and 3, the first mounting substrate 51 and the second mounting substrate 52 are illustrated in a shifted state in the x direction such that configurations of the first mounting substrate 51 and the second mounting substrate 52 can be easily understood, but, in the present embodiment, positions of the first terminals 161 and the second terminals 162 in the x direction are the same. However, as illustrated in FIG. 2 and FIG. 3, the first terminals 161 and the second terminals 162 may be shifted by a half pitch in the x direction. The first terminals 161 are connected to a first flexible wiring substrate 31 of the first mounting substrate 51 and include a terminal for receiving an image signal. The second terminals 162 are connected to a second flexible wiring substrate 32 of the second mounting substrate 52 and include a terminal for receiving an image signal.

In the electro-optical panel 100, light source light La (see FIG. 4) incident from the counter substrate 102 side is modulated while the light source light is emitted from the element substrate 101 side, and is emitted as display light. The electro-optical panel 100 includes a dust-proof glass that is placed so as to overlap at least one of a surface on a side opposite to the element substrate 101 side of the counter substrate 102 and a surface on a side opposite to the counter substrate 102 side of the element substrate 101. In the present form, the electro-optical panel 100 includes a first dust-proof glass 103 disposed to overlap on a surface on a side opposite to the element substrate 101 side of the counter substrate 102 through an adhesive or the like, and a second dust-proof glass 104 disposed to overlap and affixed to a surface on a side opposite to the counter substrate 102 side of the element substrate 101 through an adhesive or the like.

### Configuration of Holder 70

As illustrated in FIGS. 1 and 2, the holder 70 includes a first holder member 71 formed of a metal which supports the electro-optical panel 100 from one side z1 in a thickness direction, and a second holder member 72 formed of a metal which supports the electro-optical panel 100 from the other side z2 in the thickness direction. The first holder member 71 and the second holder member 72 are bonded together by, for example, a method such as stopping bolts (not illustrated) through holes 711 and 721 formed in the first holder member 71 and the second holder member 72. In addition, openings 712 and 722 through which light source light or display light passes are formed at positions overlapping a display region (pixel region 110) of the electro-optical panel 100, in the first holder member 71 and the second holder member 72.

The holder 70 includes a first heat dissipation plate portion 73 formed of a metal and disposed on a side where the plurality of mounting substrates 5 extend with respect to the first holder member 71. In addition, the holder 70 includes a second heat dissipation plate portion 74 formed of a metal and positioned on a side where the plurality of mounting substrates 5 extend with respect to the second holder member 72. The first heat dissipation plate portion 73 and the second heat dissipation plate portion 74 face each other in the z direction.

In the present form, the first heat dissipation plate portion 73 is formed separately from the first holder member 71, and the second heat dissipation plate portion 74 is formed integrally with the second holder member 72. Accordingly, the first heat dissipation plate portion 73 is fixed to the second heat dissipation plate portion 74 by a fixing member 75 in a state where a plurality of mounting substrates 5 are interposed between the first heat dissipation plate portion 73 and the second heat dissipation plate portion 74. Heat dissipation fins 730 are formed from a plurality of protrusion portions extending in the y direction in a state of being in parallel in the x direction, on a surface of the first heat dissipation plate portion 73 on a side opposite to the second heat dissipation plate portion 74, and heat dissipation fins 740 are formed from the plurality of protrusion portions extending in the y direction in a state of being in parallel in the x direction, on a surface of the second heat dissipation plate portion 74 on a side opposite to the first heat dissipation plate portion 73.

### Configuration of Mounting Substrate 5

As illustrated in FIGS. 2 to 4, on the element substrate 101 in the electro-optical device 1 of the present form, the plurality of mounting substrates 5 are connected to one side (one side 105a of the element substrate 101) of the electro-optical panel 100 in a state overlapping each other. The mounting substrate 5 is a COF (Chip On Film) mounting flexible wiring substrate on which a drive IC is mounted on a flexible wiring substrate. In the present embodiment, the two mounting substrates 5 are connected to the electro-optical panel 100 in a state of overlapping. More specifically, on the element substrate 101, the first mounting substrate 51 on which a first drive IC 21 is mounted on the first flexible wiring substrate 31, and a second mounting substrate 52 on which the second drive IC 22 is mounted on the second flexible wiring substrate 32 are connected to the electro-optical panel 100, in a state of overlapping each other in the z direction, and thereby, an image signal and the like are output from the first drive IC 21 and the second drive IC 22 to the electro-optical panel 100 via the first flexible wiring substrate 31 and the second flexible wiring substrate 32. On the first mounting substrate 51 and the second mounting substrate 52, electronic components 516 and 526 in addition to the first drive IC 21 and the second drive IC 22 are mounted at a position on a side opposite to the electro-optical panel 100 with respect to the first drive IC 21 and the second drive IC 22. The electronic components 516 and 526 are element components such as capacitors.

In an end portion 311 of the first flexible wiring substrate 31, a plurality of first output electrodes 313 are formed at a position overlapping the element substrate 101, and a plurality of first output electrodes 313 are connected to the first terminals 161 and the like, respectively. In addition, in an end portion 321 of the second flexible wiring substrate 32, a plurality of second output electrodes 323 are formed at a position overlapping the element substrate 101, and a plurality of second output electrodes 323 are connected to the second terminals 162, respectively.

The first flexible wiring substrate 31 and the second flexible wiring substrate 32 both have a certain rectangular planar shape. In addition, the first drive IC 21 and the second drive IC 22 both have a rectangular planar shape. In addition, in the first drive IC 21 and the second drive IC 22, widths (dimensions in the y direction), lengths (dimensions in the x direction), circuit configurations, and the like are equal to each other, and the first drive IC 21 and the second drive IC 22 have the same configuration. In addition, in the first mounting substrate 51 and the second mounting substrate 52, mounting positions of the first drive IC 21 and the second drive IC 22 with respect to the first flexible wiring substrate 31 and the second flexible wiring substrate 32, and widths (dimensions in the x direction), lengths (dimensions in the y direction), wiring patterns, and the like of the first flexible wiring substrate 31 and the second flexible wiring substrate 32 are equal to each other, and the first mounting substrate 51 and the second mounting substrate 52 have the same configuration.

The first flexible wiring substrate 31 and the second flexible wiring substrate 32 connected to the electro-optical panel 100 are not shifted in the x direction and are shifted in the y direction. Accordingly, a part of the second flexible wiring substrate 32 overlaps the first flexible wiring substrate 31 and is connected to the electro-optical panel 100. In the present embodiment, the first flexible wiring substrate 31 and the second flexible wiring substrate 32 are not shifted in the x direction, but, in a case where the first terminals 161 and the second terminals 162 are arranged to be shifted by a half pitch, may be connected so as to be shifted by a half pitch of the first terminal 161 (by a half pitch of the second terminal 162), corresponding to shifting of the first terminal and the second terminal. The first flexible wiring substrate 31 and the second flexible wiring substrate 32 overlap each other over a wide range in the y direction. In addition, shifting of the first flexible wiring substrate 31 and the second flexible wiring substrate 32 in the y direction corresponds to shifting between a position where the first terminals 161 are arranged and a position where the second terminals 162 are arranged. Thus, the first flexible wiring substrate 31 and the second flexible wiring substrate 32 overlap each other over a wide range in the y direction.

The first drive IC 21 is mounted on a center C1 in a length direction (y direction) of the first flexible wiring substrate 31, or on the element substrate 101 side more than the center C1. In addition, the second drive IC 22 is mounted on a center C2 in a length direction (y direction) of the second flexible wiring substrate 32, or on the element substrate 101 side more than the center C2. In the present embodiment, the first drive IC 21 is mounted on a position biased on the element substrate 101 more than the center C1 of the length direction (y direction) of the first flexible wiring substrate 31. In addition, the second drive IC 22 is mounted on a position biased on the element substrate 101 more than the center C2 of the length direction (y direction) of the second flexible wiring substrate 32.

In addition, both the first drive IC 21 and the second drive IC 22 are disposed in a region where the first flexible wiring substrate 31 and the second flexible wiring substrate 32 overlap each other. Thus, the first drive IC 21 is mounted on the first flexible wiring substrate 31 at a position where at least a part thereof overlaps the second flexible wiring substrate 32, and the second drive IC 22 is mounted on the second flexible wiring substrate 32 at a position where at least a part thereof overlaps the first flexible wiring substrate 31. In addition, the first drive IC 21 and the second drive IC 22 partially overlap each other. In contrast to this, an electronic component 516 mounted on the first flexible wiring substrate 31 and an electronic component 526 mounted on the second flexible wiring substrate 32 do not overlap each other.

A single-sided mounting substrate and a double-sided mounting substrate can be used for the first flexible wiring substrate 31 and the second flexible wiring substrate 32. In the present form, a single-sided mounting substrate is used for the first flexible wiring substrate 31 and the second flexible wiring substrate 32. Thus, output electrodes (first output electrode 313 and second output electrode 323), mounting electrodes of the first drive IC 21 and the second drive IC 22, wires, and the like (not illustrated) are formed on the one surface 316 and the one surface 326 (see FIG. 4) of the first flexible wiring substrate 31 and the second flexible wiring substrate 32. In addition, either a single-layer substrate in which wires are formed of a metal layer of the same layer and a multilayer substrate in which wires are formed of a plurality of metal layers may be used for the first flexible wiring substrate 31 and the second flexible wiring substrate 32, but, in the present form, a single-layer substrate is used for the first flexible wiring substrate 31 and the second flexible wiring substrate 32.

### Configuration of Extension Substrate

On the first mounting substrate 51, one end 411 of a first extension substrate 41 is connected to an end portion 312 on a side opposite to the element substrate 101 side with respect to the first drive IC 21 of the first flexible wiring substrate 31, and a first end portion 412 side which is the other end of the first extension substrate 41 extends to a side opposite to the element substrate 101 side. The first extension substrate 41 is configured by a flexible wiring substrate, and a plurality of first wires 415 extend from the first end portion 412 toward the one end 411. A plurality of electrodes (not illustrated) formed in the end portion 312 of the first flexible wiring substrate 31 are connected to a plurality of electrodes (not illustrated) formed in the one end 411 of the first extension substrate 41. The first end portion 412 of the first extension substrate 41 is formed in a linear shape, and a first plug 419 of a substrate-to-substrate connector is configured therein.

On the second mounting substrate 52, one end 421 of a second extension substrate 42 is connected to an end portion 322 on a side opposite to the element substrate 101 side with respect to the second drive IC 22 of the second flexible wiring substrate 32, and a second end portion 422 side which is the other end of the second extension substrate 42 extends to a side opposite to the element substrate 101 side. A plurality of electrodes (not illustrated) formed in the end portion 322 of the second flexible wiring substrate 32 are connected to a plurality of electrodes (not illustrated) formed in the one end 421 of the second extension substrate 42. The electrodes formed on the second flexible wiring substrate 32 are connected to the electrode formed on the second extension substrate 42. The second extension substrate 42 is configured by a flexible wiring substrate, and a plurality of second wires 425 extend from the second end portion 422 toward the one end 421. The second end portion 422 of the second extension substrate 42 is formed in a linear shape, and a second plug 429 of a substrate-to-substrate connector is configured therein.

Here, a dimension of the first flexible wiring substrate 31 in the y direction is smaller than a dimension of the first extension substrate 41 in the y direction, and a dimension of the second flexible wiring substrate 32 in the y direction is smaller than a dimension of the second extension substrate 42 in the y direction. A single-sided wiring substrate and a double-sided wiring substrate can be used for the first extension substrate 41 and the second extension substrate 42. In the present form, a double-sided wiring substrate is used for the first extension substrate 41 and the second extension substrate 42.

In the electro-optical device 1 in which the first mounting substrate 51 and the second mounting substrate 52 are connected to the electro-optical panel 100, the first extension substrate 41 and the second extension substrate 42 are bent in a direction where at least one of the extension substrates is separated from the other extension substrate. As a result, the first end portion 412 of the first extension substrate 41 and the second end portion 422 of the second extension substrate 42 do not overlap each other and extend on a same linear line L. In the present embodiment, the first extension substrate 41 is bent obliquely and linearly in a direction separated from the second extension substrate 42 in a middle position in the length direction (y direction), the second extension substrate 42 is bent obliquely and linearly in a direction separated from the first extension substrate 41 in a middle position in the length direction, and the first extension substrate 41 and the second extension substrate 42 are formed in a substantially symmetrical planar shape.

Here, the end portion 312 of the first flexible wiring substrate 31 and the end portion 322 of the second flexible wiring substrate 32 are disposed to be shifted in the y direction. Accordingly, lengths of the first extension substrate 41 and the second extension substrate 42 are different from each other. In the present form, the end portion 312 of the first flexible wiring substrate 31 is positioned on the element substrate 101 side from the end portion 322 of the second flexible wiring substrate 32. Accordingly, the first extension substrate 41 is longer than the second extension substrate 42 by an amount corresponding to the amount of shift between the end portion 312 of the first flexible wiring substrate 31 and the end portion 322 of the second flexible wiring substrate 32 in the y direction. Thus, the first end portion 412 of the first extension substrate 41 and the second end portion 422 of the second extension substrate 42 do not overlap each other, and extend on the linear line L parallel to an edge of the element substrate 101 in the y direction.

In this state, a first plug 419 formed in the first end portion 412 of the first extension substrate 41 is coupled to a first socket 619 formed on the wiring substrate 60 configured by a rigid substrate, and a second plug 429 formed in the second end portion 422 of the second extension substrate 42 is coupled to a second socket 629 formed on the wiring substrate 60 configured by a rigid substrate. The wiring substrate 60 inputs various power supply voltages and various signals from a high-level circuit to the first drive IC 21 via the first extension substrate 41 and the first flexible wiring substrate 31. As a result, the first drive IC 21 outputs the various signals to the element substrate 101 via the first flexible wiring substrate 31. In addition, the wiring substrate 60 inputs various power supply voltages and various signals from a high-level circuit to the second drive IC 22 via the second extension substrate 42 and the second flexible wiring substrate 32. As a result, the second drive IC 22 outputs the various signals to the element substrate 101 via the second flexible wiring substrate 32.

In the present form, double-sided wiring substrates are used as the first extension substrate 41 and the second extension substrate 42. Thus, some parts of the first wire 415 and the second wire 425 may be formed on one surface of the first extension substrate 41 and one surface of the second extension substrate 42, and the other parts and ground wires of the first wires 415 and the second wires 425 may be formed on the other surfaces. In addition, a conductive pattern to which a ground potential is applied may be formed on all the other surfaces of the first extension substrate 41 and the second extension substrate 42.

### Heat Dissipation Structure

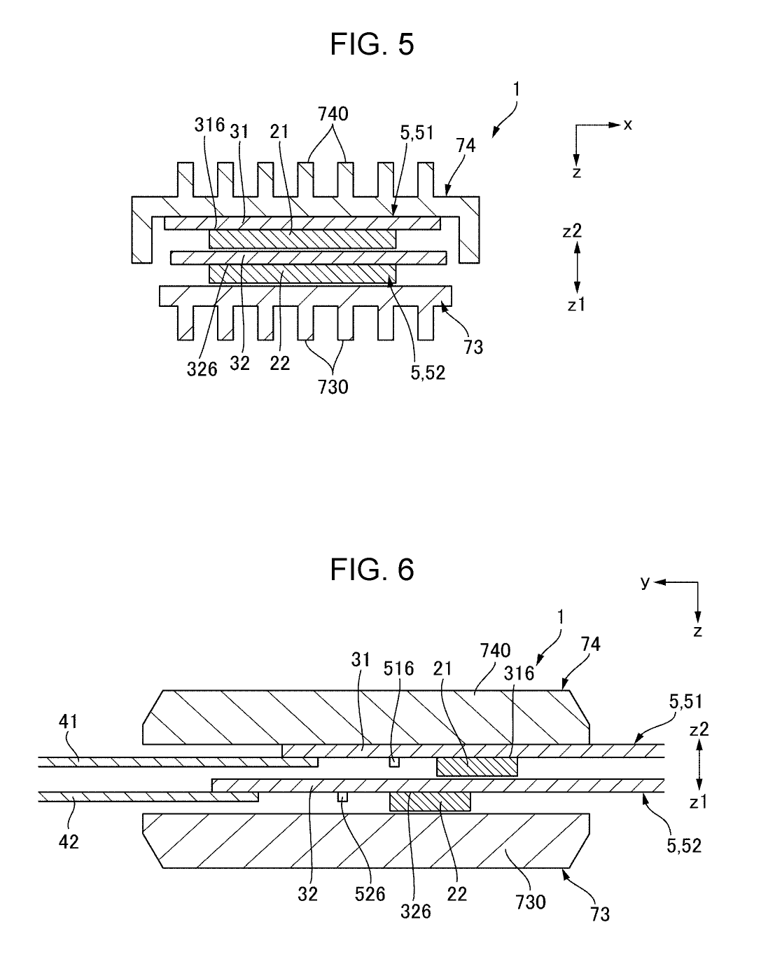

FIG. 5 is a cross-sectional view schematically illustrating a state where the electro-optical device 1 illustrated in FIG. 1 is cut along a line V-V. FIG. 6 is a cross-sectional view schematically illustrating a state where the electro-optical device 1 illustrated in FIG. 1 is cut along a line VI-VI.

In the electro-optical device 1 according to the present form illustrated in FIG. 4, the sum total of thicknesses of the flexible wiring substrates (the first flexible wiring substrate 31 and the second flexible wiring substrate 32) used for the plurality of mounting substrates 5 (the first mounting substrate 51 and the second mounting substrate 52) 32) and thicknesses of the drive ICs (the first drive IC 21 and the second drive IC 22) is equal to or less than the thickness t of the electro-optical panel 100. Thus, as illustrated in FIGS. 5 and 6, the first heat dissipation plate portion 73 and the second heat dissipation plate portion 74 are disposed on both sides of a part where the drive ICs (the first drive IC 21 and the second drive IC 22) in the thickness direction (z direction) are disposed in the mounting substrates 5 (the first mounting substrate 51 and the second mounting substrate 52). Thus, heat generated by the first drive IC 21 and the second drive IC 22 can efficiently escape from the first heat dissipation plate portion 73 and the second heat dissipation plate portion 74.

### Electrical Configuration of Electro-Optical Device 1

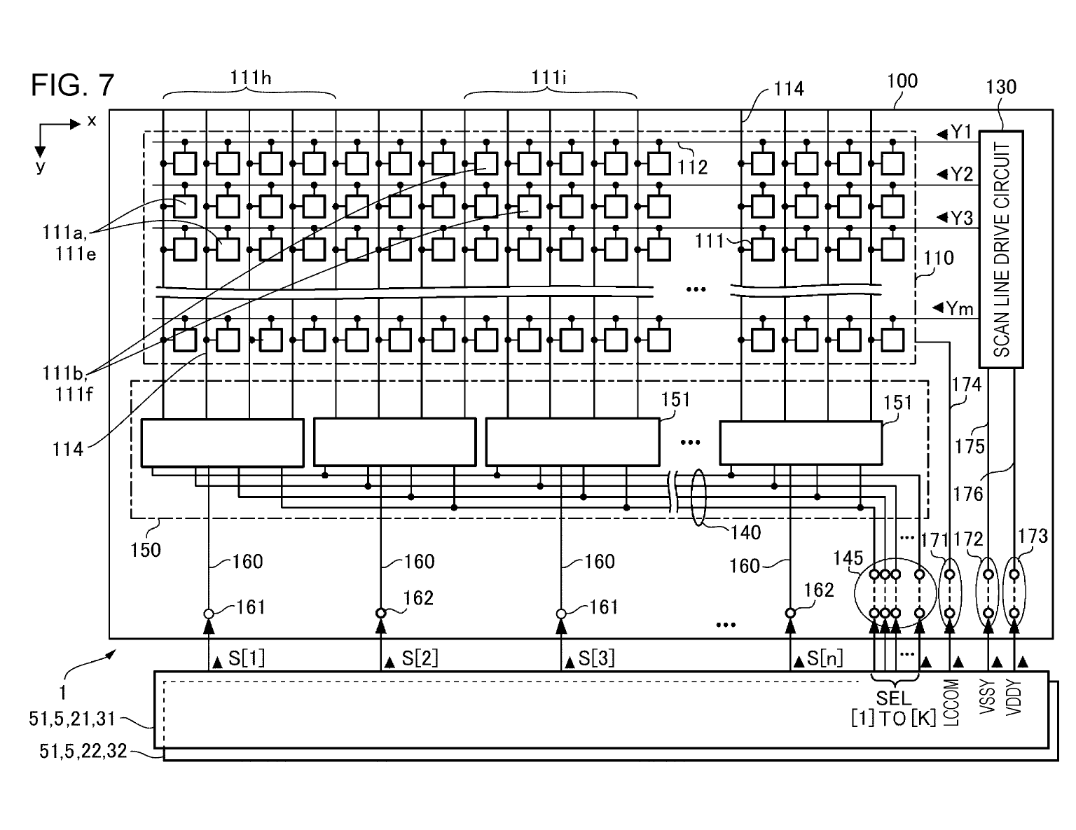

FIG. 7 is an explanatory diagram illustrating one aspect of an electrical configuration of the electro-optical device 1 illustrated in FIG. 1. As illustrated in FIG. 7, the electro-optical panel 100 includes a pixel region 110 (display region), a scan line drive circuit 130, a data line selection circuit 150 (selection circuit), n image signal lines 160, n image signal input terminals (the first terminals 161 and the second terminals 162), k selection signal lines 140, k selection signal input terminals 145, a plurality of power supply terminals 171, 172, and 173, and power supply lines 174, 175, and 176 corresponding to the power supply terminals 171, 172, and 173, respectively. n is an integer of 1 or larger, and k is an integer of 2 or larger. In the form illustrated in FIG. 7, k=4. The elements are formed on the element substrate 101 illustrated in FIG. 2. On the element substrate 101, the data line selection circuit 150 is formed along one side of a peripheral portion of the pixel region 110, and the scan line drive circuit 130 is formed along another side crossing a side where the data line selection circuit 150 is formed.

The first drive IC 21 and the second drive IC 22 output image signals indicating an image to be displayed on the electro-optical panel 100 in accordance with a control signal, a control signal, image data, and the like which are input from an external high-level circuit (not illustrated) via the first flexible wiring substrate 31 and the second flexible wiring substrate 32 (see FIG. 2). The electro-optical panel 100 displays an image, based on a clock signal and an image signal which are input from the first drive IC 21, the first flexible wiring substrate 31, the second drive IC 22, and the second flexible wiring substrate 32. The first drive IC 21 and the second drive IC 22 have the same configuration and output the same signal except for the image signal.

The pixel region 110 displays an image. The pixel region 110 includes m scan lines 112, (k×n) data lines 114, and (m×k×n) pixels 111. m is an integer of 1 or larger. The pixel 111 includes a pixel electrode 118. The pixel 111 is provided corresponding to an intersection between the scan line 112 and the data line 114, and is arranged in a matrix of m rows×(k×n) columns. The scan lines 112 transmit scan signals Y1, Y2, Y3, . . . , Ym, and are provided in a row direction (x direction) from the scan line drive circuit 130. The data lines 114 transmit data signals, and are provided in a column direction (y direction) from the data line selection circuit 150.

In the pixel region 110, (k×m) pixels 111 corresponding to the k (column) data lines 114 form one pixel group (block). For example, there are provided a first pixel group 111h in which a plurality of (k columns) first pixel columns 111e, each including a plurality of (m) first pixels 111a arranged in the y direction, are arranged in the X direction, and a second pixel group 111i in which a plurality of (k columns) second pixel columns 111f, each including a plurality of (m) second pixels 111b arranged in the y direction, are arranged in the X direction. Here, the pixels 111 belonging to the same pixel group are connected to the same image signal line 160 via the data line selection circuit 150. Accordingly, the electro-optical panel 100 includes n (rows) pixel groups divided into n blocks by n (column) image signal lines 160 or n image signal input terminals (the first terminals 161 and the second terminals 162).

The scan line drive circuit 130 selects a row to write data from among the plurality of pixels 111 arranged in a matrix. Specifically, the scan line drive circuit 130 outputs a scan signal for selecting one scan line 112 from among the plurality of scan lines 112. The scan line drive circuit 130 supplies the scan signals Y1, Y2, Y3, . . . , Ym to the scan lines 112 of the first row, the second row, the third row, . . . , the m-th row. The scan signals Y1, Y2, Y3, . . . , Ym become, for example, a high level sequentially and exclusively.

In each pixel group, the data line selection circuit 150 selects a column (pixel column) of pixels 111 to which an image signal is written. Specifically, the data line selection circuit 150 selects at least one data line 114 from among the k data lines 114 belonging to the pixel group in accordance with the selection signals SEL[1] to SEL[k]. The data line 114 is connected to one image signal line 160 one by one by the data line selection circuit 150 by using k data lines as one unit. In the present form, the data line selection circuit 150 has n demultiplexers 151 corresponding to each of n pixel groups.

The image signal lines 160 connect the image signal input terminals (the first terminals 161 and the second terminals 162) to the data line selection circuit 150. The image signal line 160 transmits the image signals S (S[1] to S[n]) input from the first flexible wiring substrate 31 and the second flexible wiring substrate 32 via the image signal input terminals (the first terminals 161 and the second terminals 162) to the data line selection circuit 150, and is provided in n columns (pieces), corresponding to n image signal input terminals (the first terminals 161 and the second terminals 162) or each of n pixel groups. The image signal S indicates data to be written to the pixel 111. Here, an “image” means a still image or a moving image. One image signal line 160 is connected to k data lines 114 via a data line selection circuit 150. Thus, in the image signal S, data supplied to the k data lines 114 are time-division-multiplexed.

The selection signal lines 140 connect the selection signal input terminals 145 to the demultiplexers 151 of the data line selection circuit 150. The selection signal lines 140 (140[1] to 140[k]) transmit the selection signals SEL (SEL[1] to SEL[k]) input from the selection signal input terminal 145 (145[1] to 145[k]), and k selection signal lines are provided. The selection signals SEL sequentially become a high level.

The image signal input terminals (the first terminals 161 and the second terminals 162) are connected to the first flexible wiring substrate 31 and the second flexible wiring substrate 32, and the image signal S[j] is supplied therethrough (j is an integer satisfying 1≤j≤n). In this example, the image signals S[1], S[3], S[5], . . . , S[2t−1] are supplied from the first drive IC 21 to the image signal input terminals (the first terminals 161 and the second terminal 162) corresponding to the image signal lines 160 of odd-numbered columns among the first column, the third column, the fifth column, . . . , the (2t−1)th column (t is an integer satisfying 1≤t≤n/2). In addition, the image signals S[2], S[4], S[6], . . . , S[2t] are supplied from the second drive IC 22 to the image signal input terminals (the first terminals 161 and the second terminal 162) corresponding to the image signal lines 160 of even-numbered columns among the second column, the fourth column, the sixth column, . . . , the (2t)th column. The image signals S are so-called data signals, and analog signals having different waveforms according to display of an image are supplied to the image signal input terminals (the first terminals 161 and the second terminals 162).

The selection signal input terminals 145 are connected to the first flexible wiring substrate 31 and the second flexible wiring substrate 32, and selection signals SEL configured by pulse signals are supplied thereto. The selection signals SEL are timing signals for selecting the data lines 114 in the data line selection circuit 150. The selection signal input terminals 145 include a terminal to which the first flexible wiring substrate 31 is connected and a terminal which is connected to the second flexible wiring substrate 32, and the selection signal SEL is supplied from both or one of the first drive IC 21 of the first flexible wiring substrate 31 and the second drive IC 22 of the second flexible wiring substrate 32. In the present form, the selection signals SEL having the same waveform are supplied to the selection signal input terminals 145 corresponding to each of the first flexible wiring substrate 31 and the second flexible wiring substrate 32. Thus, the selection signal input terminals 145 are illustrated so as not to be distinguished as the terminal to which the first flexible wiring substrate 31 is connected and the terminal connected to the second flexible wiring substrate 32, but may be distinguished as the terminal to which the first flexible wiring substrate 31 is connected and the terminal to which the second flexible wiring substrate 32 is connected like the first terminal 161 and the second terminal 162.

The power supply terminal 171, the power supply terminal 172, and the power supply terminal 173 are connected to the first flexible wiring substrate 31 and the second flexible wiring substrate 32, and power supply voltages are supplied from a high-level circuit thereto via the first flexible wiring substrate 31 and the second flexible wiring substrate 32 without passing through the first drive IC 21 and the second drive IC 22. The power supply voltages are used as power sources in the electro-optical panel 100, and are DC voltages in this example. The power supply terminal 171 supplies a voltage LCCOM, the power supply terminal 172 supplies a voltage VSSY, and the power supply terminal 173 supplies a voltage VDDY. The voltage LCCOM is a reference potential of a voltage applied to a liquid crystal layer. The voltage VSSY is a power supply potential on a low voltage side of the scan line drive circuit 130. The voltage VDDY is a power supply potential on a high voltage side of the scan line drive circuit 130. The power supply terminals 171, 172, 173 are illustrated so as not to be distinguished as the terminal to which the first flexible wiring substrate 31 is connected and the terminal connected to the second flexible wiring substrate 32, but may be distinguished as the terminal to which the first flexible wiring substrate 31 is connected and the terminal connected to the second flexible wiring substrate 32 like the first terminal 161 and the second terminal 162.

Each of the power supply terminals 171, 172, and 173 may be provided on both sides in the x direction. This is to correspond to a configuration in which the scan line drive circuit 130 is provided on each of the left and right sides of the element substrate 101. In the present form, only one scan line drive circuit 130 is configured, and thus, the power supply terminals 172 and 173 are provided only on one side in the x direction.

In the present embodiment, data to be written to the pixels 111 of the [k×j−k+1]th column to the [k×j]th column which are the k pixels 111 of the corresponding pixel group is time-division-multiplexed in the image signal S[j]. In addition, in a case where S[j] is an odd-numbered S[2t−1], the image signal is supplied from the first drive IC 21 to the data line 114 of the odd-numbered pixel group. In a case where S[j] is an even-numbered S[2t], the image signal is supplied from the second drive IC 22 to the data line 114 of the even-numbered pixel group. According to such a configuration, two drive ICs of the first drive IC 21 and the second drive IC 22 are used, and thus, it is possible to write data to twice as many pixels in one cycle as compared with a case of using one drive IC. As described above, by disposing the first terminal 161 and the second terminal 162, a high definition, high quality, and compact electro-optical device 1 can be realized.

### Main Effect of Present Form

As described above, in the electro-optical device 1 according to the present form, since the plurality of mounting substrates 5 (the first mounting substrate 51 and the second mounting substrate 52) connected to the electro-optical panel 100 overlap each other, it is possible to reduce a size of the electro-optical panel 100 (electro-optical device 1). In addition, since the plurality of mounting substrates 5 (the first mounting substrate 51 and the second mounting substrate 52) connected to the electro-optical panel 100 have all the same configurations including sizes of the flexible wiring substrates (the first flexible wiring substrate 31 and the second flexible wiring substrate 32) and the mounting positions of the drive ICs (the first drive IC 21 and the second drive IC 22), there is no need to prepare a plurality of types of mounting substrates 5. Thus, cost can be reduced. Therefore, even if a plurality of wiring substrates on which drive ICs are mounted are used, it is possible to realize an electro-optical device 1 that can be miniaturized and can reduce an increase in cost.

In addition, in the plurality of mounting substrates 5, a total sum of thicknesses of the first flexible wiring substrate 31 and the second flexible wiring substrate 32 and thicknesses of the drive ICs (the first drive IC 21 and the second drive IC 22) is equal to or less than a thickness t of the electro-optical panel 100. Thus, as illustrated in FIGS. 5 and 6, there is an advantage that thicknesses of parts where the first heat dissipation plate portion 73 and the second heat dissipation plate portion 74 are provided on both sides of a part where the drive ICs (the first drive IC 21 and the second drive IC 22) are mounted in a thickness direction can be reduced, on the plurality of mounting substrates 5 (the first mounting substrate 51 and the second mounting substrate 52).

In addition, in the plurality of mounting substrates 5, parts of the respective drive ICs (the first drive IC 21 and the second drive IC 22) overlap each other in a thickness direction. Accordingly, since the drive ICs that are heat generating sources are collected, it is easy to take measures against heat by using the first heat dissipation plate portion 73 and the second heat dissipation plate portion 74.

In addition, the first drive IC 21 is mounted on the center of the first flexible wiring substrate 31 in a length direction or on the element substrate 101 side from the center, and the second drive IC 22 is mounted on the center of the second flexible wiring substrate 32 in a length direction or on the element substrate 101 side from the center. Accordingly, deterioration hardly occurs in analog signals output from the first drive IC 21 and the second drive IC 22 to the element substrate 101.

In addition, since each of the plurality of mounting substrates 5 is a single-sided substrate, cost can be reduced. In addition, in each of the plurality of mounting substrates 5, the first extension substrate 41 and the second extension substrate 42 which are flexible wiring substrates are connected to the end portions 312 and 322 of the first flexible wiring substrate 31 and the second flexible wiring substrate 32. Thus, since the first flexible wiring substrate 31 and the second flexible wiring substrate 32 used for the mounting substrate 5 can be shortened, cost can be reduced. Particularly, the first drive IC 21 is mounted on the first flexible wiring substrate 31 at a position at least a part thereof overlaps the second flexible wiring substrate 32, and the second drive IC 22 is mounted on the second flexible wiring substrate 32 such that at least a part thereof overlaps the first flexible wiring substrate 31, and the first drive IC 21 and the second drive IC 22 are both located at a position close to the element substrate 101. Accordingly, when connecting the first extension substrate 41 and the second extension substrate 42 to the first flexible wiring substrate 31 and the second flexible wiring substrate 32, the expensive first flexible wiring substrate 31 and the expensive second flexible wiring substrate 32 can be significantly shortened. Thus, it is possible to reduce costs of the first flexible wiring substrate 31 on which the first drive IC 21 is mounted and the second flexible wiring substrate 32 on which the second drive IC 22 is mounted.

In addition, since the first end portion 412 of the first extension substrate 41 and the second end portion 422 of the second extension substrate 42 extend on the same linear line L without overlapping each other, work is easily done when the first end portion 412 of the first extension substrate 41 and the second end portion 422 of the second extension substrate 42 are connected to a high-level circuit or the like. For example, if the first end portion 412 of the first extension substrate 41 and the second end portion 422 of the second extension substrate 42 overlap each other, the second end portion 422 needs to be inserted into the second socket 629 of a connector by turning over the first end portion 412. According to the present form, it is possible to insert the second end portion 422 into the second socket 629 of the connector without requiring such labor. In addition, since the first end portion 412 and the second end portion 422 extend on the same linear line L, the first socket 619 and the second socket 629 can be linearly disposed on the wiring substrate 60. Thus, it is possible to efficiently perform the work of inserting the first end portion 412 and the second end portion 422 into the first socket 619 and the second socket 629.

### Another Embodiment

A case where the number of mounting substrates 5 is two is exemplified in the above-described embodiment, but the invention may be applied to a case where the number of mounting substrates 5 is three or more.

### Example of Mounting on Electronic Apparatus

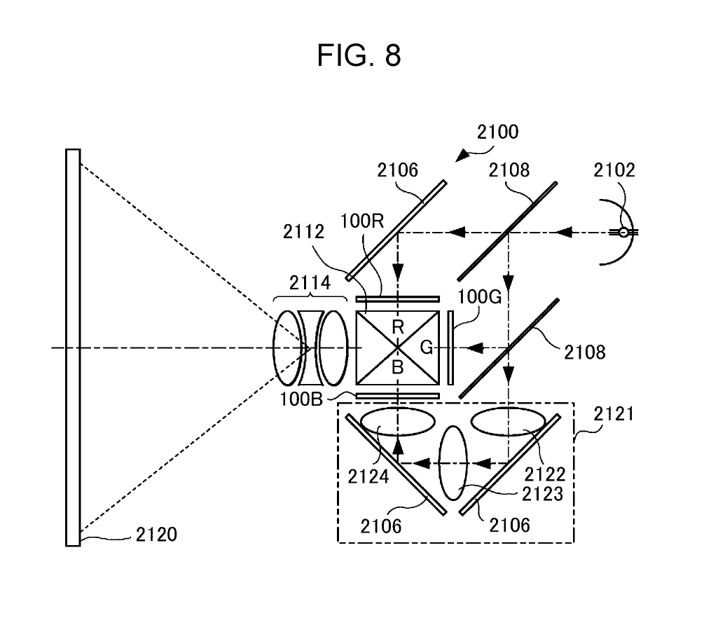

An electronic apparatuses which uses the electro-optical device 1 according to the above-described embodiment will be described. FIG. 8 is a schematic configuration view of a projection type display device (electronic apparatus) which uses the electro-optical device 1 to which the invention is applied. A projection type display device 2100 illustrated in FIG. 8 is an example of an electronic apparatus which uses the electro-optical device 1. In the projection type display device 2100, the electro-optical device 1 is used as a light valve, and high-definition and bright display can be performed without enlarging the device. As illustrated in the figure, a lamp unit 2102 (light source unit) including a white light source such as a halogen lamp is provided inside the projection type display device 2100. Projected light emitted from the lamp unit 2102 is separated into three primary colors of R (red), G (green), and B (blue) by three mirrors 2106 and two dichroic mirrors 2108 arranged therein. The separated projection light is guided to light valves 100R, 100G and 100B corresponding to the respective primary colors. Since light of the B color has a long optical path as compared with the other R color and G color, the light of the B color is guided through a relay lens system 2121 including an incident lens 2122, a relay lens 2123, and an emission lens 2124 so as to prevent loss from being made.

In the projection type display device 2100, three sets of liquid crystal devices, each including the electro-optical device 1, are provided corresponding to the R, G, and B colors, respectively. Configurations of the light valves 100R, 100G, and 100B are the same as the configuration of the above-described electro-optical panel 100, and are connected to a high-level circuit in the projection type display device 2100 via the first extension substrate 41 and the second extension substrate 42, respectively. Image signals for designating gradation levels of primary color components of each of R color, G color, and B color are respectively supplied from an external high-level circuit, processed by a high-level circuit in the projection type display device 2100, and the light valves 100R, 100G, and 100B are respectively driven. Lights modulated by the light valves 100R, 100G, and 100B, respectively, are incident on a dichroic prism 2112 from three directions. Then, in the dichroic prism 2112, the R color light and the B color light are reflected at 90 degrees, and the G color light transmits. Thus, after images of the respective primary colors are synthesized, a color image is projected on a screen 2120 by a projection lens group 2114 (projection optical system).

### Another Projection Type Display Device

An LED light source or the like for emitting light of each color may be used as a light source unit for the projection type display device, and the projection type display device is configured such that color lights emitted from the LED light sources are supplied to other liquid crystal devices, respectively.

### Another Electronic Apparatus

An electronic apparatus including the electro-optical device 1 to which the invention is applied is not limited to the projection type display device 2100 according to the above-described embodiment. The electronic apparatus may be used for an electronic device, for example, a projection type head up display (HUD), a direct view type head mounted display (HMD), a personal computer, a digital still camera, a liquid crystal television, or the like.

This application claims priority to Japan Patent Application No. 2017-019309 filed Feb. 6, 2017, the entire disclosures of which are hereby incorporated by reference in their entireties.

What is claimed is:

1. An electro-optical device which includes an electro-optical panel, a first mounting substrate that is connected to one side of the electro-optical panel, and a second mounting substrate that is connected to the one side of the electro-optical panel, and in which at least parts of the first mounting substrate and the second mounting substrate overlap each other in plan view,
wherein the first mounting substrate includes a first flexible wiring substrate and a first drive IC that is mounted on one surface of the first flexible wiring substrate,
wherein the second mounting substrate includes a second flexible wiring substrate and a second drive IC that is mounted on one surface of the second flexible wiring substrate,
wherein at least parts of the first drive IC and the second drive IC overlap each other in plan view, and
wherein a total sum of thicknesses of the first mounting substrate and the second mounting substrate is equal to or less than a thickness of the electro-optical panel at a place where the first drive IC and the second drive IC overlap each other.

2. The electro-optical device according to claim 1,
wherein the first mounting substrate and the second mounting substrate are the same in size.

3. The electro-optical device according to claim 2,
wherein a mounting position of the first drive IC on the first mounting substrate and a mounting position of the second drive IC on the second mounting substrate are the same as each other.

4. The electro-optical device according to claim 1,
wherein the first mounting substrate includes a first electronic component in addition to the first drive IC mounted on the first flexible wiring substrate,
wherein the second mounting substrate includes a second electronic component in addition to the second drive IC mounted on the second flexible wiring substrate, and
wherein the first electronic component and the second electronic component do not overlap each other in plan view.

5. The electro-optical device according to claim 1,
wherein the first mounting substrate includes the first flexible wiring substrate and a first extension substrate which is connected to the first flexible wiring substrate, and
wherein the second mounting substrate includes the second flexible wiring substrate and a second extension substrate which is connected to the second flexible wiring substrate.

6. The electro-optical device according to claim 1, further comprising:
a holder that supports the electro-optical panel from both sides in a thickness direction,
wherein the holder includes a first holder member that supports the electro-optical panel from one side in a thickness direction, a second holder member that supports the electro-optical panel from the other side in a thickness direction, a first heat dissipation plate portion that overlaps a part where the drive IC of each of a plurality of the mounting substrates is mounted from one side of the electro-optical panel in a thickness direction, and a second heat dissipation plate portion that overlaps the part where the drive IC of each of the plurality of mounting substrates is mounted from the other side of the electro-optical panel in the thickness direction.

7. The electro-optical device according to claim 1,
wherein the electro-optical panel includes an element substrate on which pixel electrodes are formed, a counter substrate facing the element substrate, and a dust-proof glass that is disposed so as to overlap on at least one of a surface of the counter substrate on a side opposite to the element substrate and a surface of the element substrate on a side opposite to the counter substrate.

8. An electronic apparatus comprising:
the electro-optical device according to claim 1.

9. An electronic apparatus comprising:
the electro-optical device according to claim 2.

10. An electronic apparatus comprising:
the electro-optical device according to claim 3.

11. An electronic apparatus comprising:
the electro-optical device according to claim 4.

12. An electronic apparatus comprising:
the electro-optical device according to claim 5.

13. An electronic apparatus comprising:
the electro-optical device according to claim 6.

14. An electronic apparatus comprising:
the electro-optical device according to claim 7.
